(19) United States
(12) Patent Application Publication
(10) Pub. No.: US 2006/0094247 A1
(43) Pub. Date: May 4, 2006

(54) Method for producing a stepped edge profile comprised of a layered construction

(75) Inventors: Jerome Assal, Zurich (CH); Simon Eicher, Affoltern am Albis (CH); Erich Nanser, Lenzburg (CH)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: ABB Schweiz AG, Baden (CH)

(21) Appl. No.: 10/532,313

(22) PCT Filed: Oct. 17, 2003
(86) PCT No.: PCT/CH03/00681

§ 371 Date: Nov. 14, 2005

(30) Foreign Application Priority Data
Oct. 23, 2002 (EP) 02405909.9

(51) Int. Cl. H01L 21/302; H01L 21/461

(52) U.S. Cl. 438/735; 438/739; 438/736

(57) ABSTRACT

In a method for forming a stepped profile from a layer sequence comprising a first patterning step, in which a first layer partial sequence is removed apart from a first residual layer partial sequence, a second patterning step, in which a second layer partial sequence located below the first layer partial sequence is partially removed by means of etching with a second etchant, and a third patterning step, in which a third layer partial sequence located below the second layer partial sequence is partially removed by means of etching with a third etchant, according to the invention, a region of the second layer partial sequence that is located below the first residual layer partial sequence is removed in the second patterning step and the first projection of the first residual layer partial sequence is removed in the third patterning step.

### TECHNICAL FIELD

The present invention is concerned with the field of semiconductor process technology. It relates to a method for fabricating a stepped profile from a layer sequence according to the preamble of the first patent claim.

### PRIOR ART

In order to form a patterning of metallic layers applied on semiconductors, a multiplicity of known techniques are usually used in a plurality of successive patterning steps. It is often the case here that firstly a photoresist is applied as a protective layer to a metallic layer or a metallic layer sequence. A resulting first photoresist layer is subsequently exposed through a first exposure mask. Afterward, depending on the constitution of the photoresist, either an exposed or an unexposed region of the photoresist layer can be removed, so that the unexposed or the exposed region remains. The metallic layer or layer sequence is then etched in one or more patterning steps. Various etching methods are available in this case: etching in aqueous solution, dry etching, reactive ion etching or a combination of these methods. In this case, the residual region of the photoresist layer prevents or delays etching of regions of the metallic layer or layer sequence that are located below it.

In this case, a not inconsiderable total outlay may result, particularly if a complex patterning has to be performed and/or a layer sequence comprising a multiplicity of individual layers has to be etched. The number of required patterning steps increases in such cases, different etching methods or at least different etchants often being required for different patterning steps. In some instances, it is also necessary in this case, between two patterning steps, for one or more further photoresist layers to be applied again and exposed through further exposure masks and for exposed or unexposed regions of the further photoresist layers to be removed.

When a plurality of masks are used, however, the overall process becomes increasingly inaccurate, in particular on account of orientation problems when positioning the exposure masks.

An exemplary application for the patterning of layer sequences is applying electrodes on semiconductor chips in particular for semiconductor chips which are used in pressure-contact-connectable power semiconductor modules with a module housing that is not hermetically sealed. Such semiconductor chips advantageously comprise a layer sequence made of Ti, Ni and Ag for the purpose of electrical contact-connection, a Ti layer being located closest to the semiconductor chip. Depending on an internal structure of the semiconductor chip and a fabrication process, this layer sequence has to be patterned at various locations, for example in a region between a main electrode and a gate electrode. In this case, typical structure sizes are generally less than 0.5 mm.

When patterning the Ti/Ni/Ag layer sequence by means of etching, care has to be taken to ensure that no undercut regions are formed, since contaminants and/or deposits may form in such regions during the fabrication process or operation of the semiconductor chips and they are difficult to remove, but may adversely influence an operating behavior of the semiconductor chips or may even lead to the destruction thereof.

### SUMMARY OF THE INVENTION

Consequently, it is an object of the invention to specify a method of the type mentioned in the introduction which manages with the fewest possible patterning steps, it not being necessary to apply protective layers between the patterning steps.

This and other objects are achieved by means of a method for forming a stepped profile from a layer sequence having the features of the independent patent claim. In this case, in a first, second and third patterning step, respectively, a first, second and third layer partial sequence are in each case removed partially i.e. apart from a first, second and third residual layer partial sequence, respectively. In the second and third patterning steps, this is done by the action of a second and third etchant respectively. According to the invention, in the second patterning step, the first residual layer partial sequence is in this case undercut, i.e. a region of the second layer partial sequence that lies below it is removed. A first projection of the first residual layer partial sequence that is formed in this case is removed again in the third patterning step in order to obtain the desired stepped profile.

In one preferred variant of the method, a first etchant is used in this case in the first patterning step, which first etchant is preferably substantially identical chemically to the third etchant used in the third patterning step. In this case, an identical etching bath may advantageously be used for the first and third patterning steps, which further reduces the complexity of the method and permits the method to be carried out more economically and with greater ecofriendliness.

Further advantageous refinements of the invention are specified in the dependent claims, advantages and features becoming evident from the detailed description below of preferred variants of the invention in conjunction with the drawing.

### BRIEF DESCRIPTION OF THE DRAWINGS

FIG. 1 shows a starting product for the method according to the invention.

FIG. 2 shows a first intermediate product resulting from the first patterning step.

FIG. 3 shows a second intermediate product resulting from the second patterning step.

FIG. 4 shows a final product resulting from the third patterning step.

FIG. 5 shows a semiconductor chip with a stepped profile formed according to the method according to the invention after the removal of a photoresist layer.

The reference symbols used in the drawings and their meaning are summarized in the List of Reference Symbols. In principle, identical reference symbols designate identical parts.

### WAYS OF EMBODYING THE INVENTION

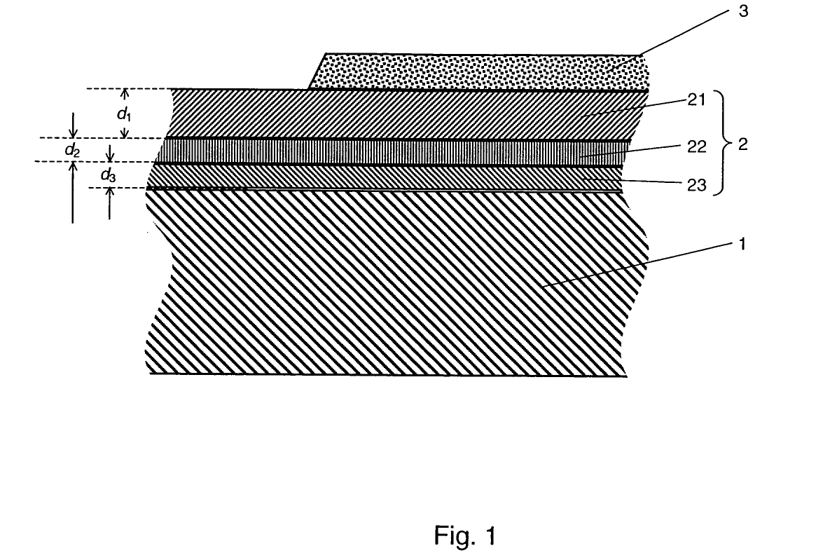

FIG. 1 shows a starting product for the method according to the invention, comprising a layer sequence 2—applied on a semiconductor chip 1—made of an Ag layer 21 as first layer partial sequence, an Ni layer 22 as second layer partial sequence and a Ti layer 23 as third layer partial sequence. A first thickness d₁ of the Ag layer 21 is preferably a few micrometers, and a second thickness d₂ of the Ni layer 22 and a third thickness d₃ of the Ti layer 23 are preferably in each case a few tenths of a micrometer. A part of the Ag layer 21 is covered by a photoresist layer 3 as a protective layer.

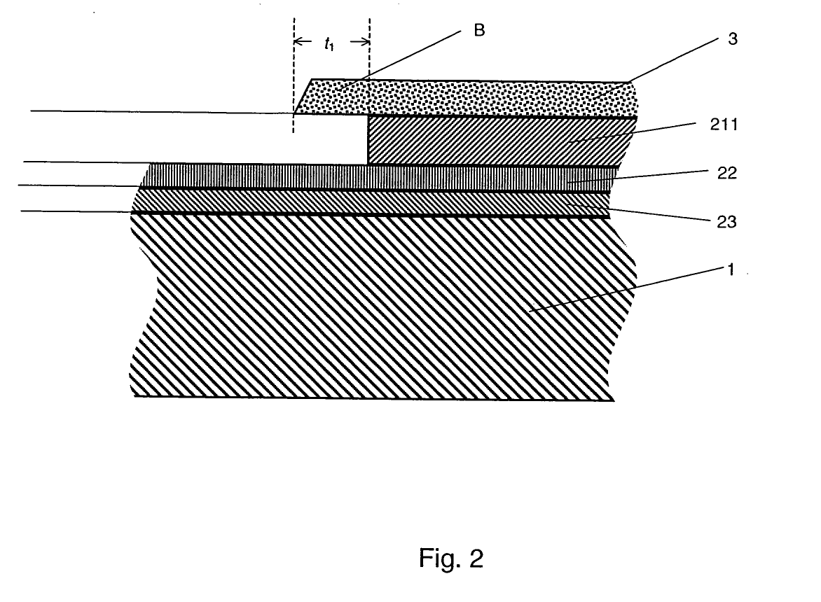

In order to form a stepped profile in the layer sequence 2, first of all, in a first patterning step, the Ag layer 21 is etched using a chemical solution comprising hydrogen peroxide (H₂O₂), ammonium hydroxide (NH₄OH) and water (H₂O) as a first etchant. A solution in which H₂O₂, NH₄OH and H₂O are present in a volume ratio of H₂O₂:NH₄OH:H₂O=1:x:y, is preferably used as the first etchant, where 0.5<x<2.0 and 4.0<y<10.0 are preferably chosen. Preferably, the first patterning step is effected at a temperature T₁, preferably where 10° C.<T₁<30° C., during a time of a few minutes to a few tens of minutes, advantageously in a first etching bath. In this case, the photoresist layer 3 is preferably undercut, so that a second projection B arises in the photoresist layer 3, said projection having a depth t₁, undercutting preferably being effected to an extent such that t₁>d₁. This ensures that the Ag layer 21 is removed completely and without any residues where it is not covered by photoresist. In this case, the Ni layer 22 is essentially not attacked in the first patterning step. A first intermediate product resulting from the first patterning step with an Ag residual layer 211 as first residual layer partial sequence can be seen in FIG. 2.

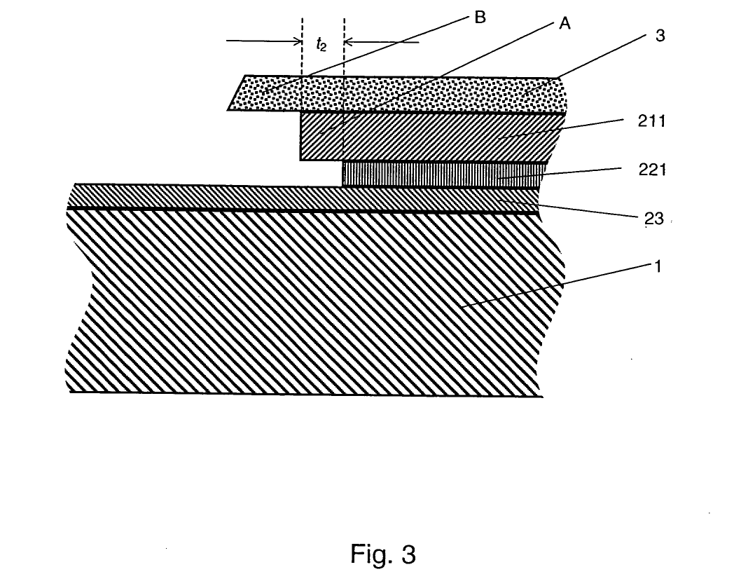

In a second patterning step, proceeding from the first intermediate product from FIG. 2, the Ni layer 22 is etched using an aqueous solution of nitric acid (HNO₃) as a second etchant, so that only an Ni residual layer 221 remains. 2.0<z<8.0 is preferably chosen for the volume ratio of HNO₃:H₂O=1:z. The second patterning step is effected at a temperature T₂, preferably where 30° C.<T₂<50° C., preferably during less than ten minutes. In this case, a region of the Ni layer 22 that is located below the Ag residual layer 211 is removed, thus giving rise to a first projection A of the Ag residual layer 211, said projection having a depth t₂. A second intermediate product resulting after the second patterning step can be seen in FIG. 3.

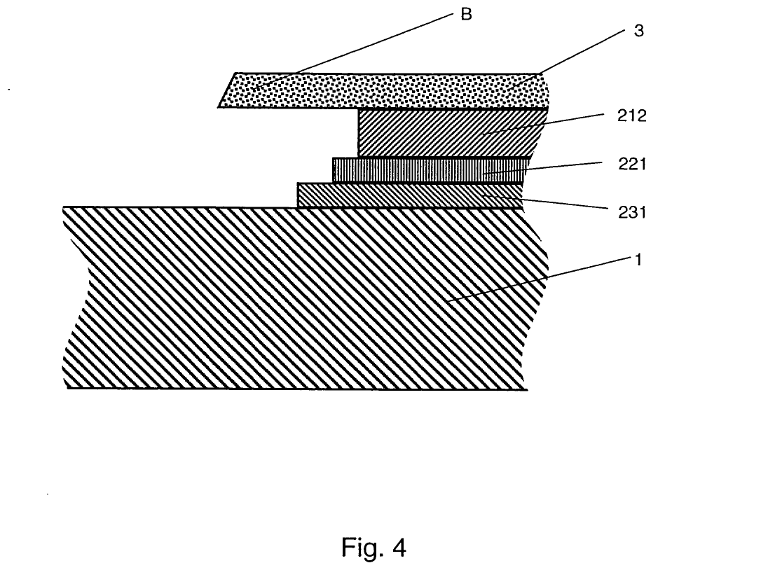

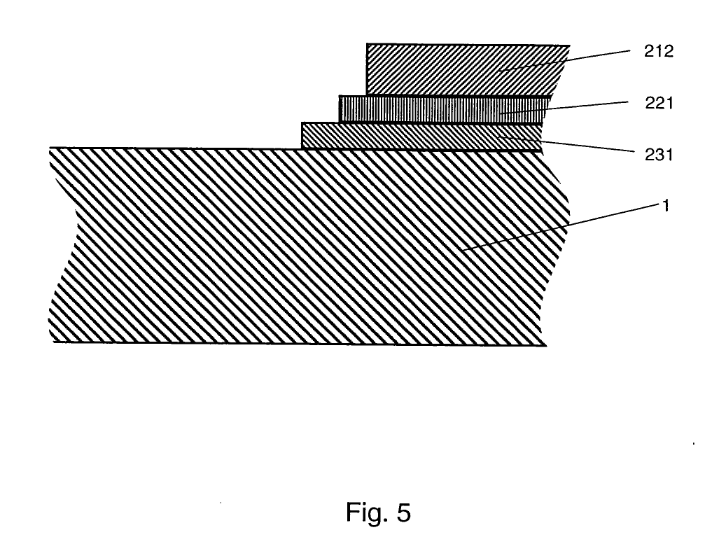

In a third patterning step, proceeding from the second intermediate product from FIG. 3, the Ti layer 23 is etched. In this case, the third etchant used is once again a chemical solution comprising hydrogen peroxide (H₂O₂), ammonium hydroxide (NH₄OH) and water (H₂O), which are preferably present in the same volume ratio as in the first etchant. The third patterning step may be advantageously effected in the first etching bath. In this case, the Ag residual layer 211 is etched at the same time as the Ti layer to form an Ag final layer 212, so that the first projection A is dissolved, the Ni layer 22 is overetched, and the desired stepped profile is finally formed. In this case, the first projection A firstly acts as a chemical mask which prevents a region of the Ti layer 22 that is located below the first projection A from being dissolved by the third etchant or which at least greatly slows down such dissolution. Once the first projection A has been dissolved, the Ni residual layer 221, which is not attacked by the third etchant, acts as a conventional mask for the Ti layer 23. Since Ti is etched by the third etchant significantly more slowly than Ag, an undercut, i.e. a formation of a third projection of the Ni residual layer 221, iS effectively prevented. FIG. 4 shows a third intermediate product of the method according to the invention resulting from the third patterning step. In an advantageous manner, the photoresist layer 3 is also finally removed, thereby giving rise to the semiconductor chip 1 with a stepped profile formed according to the method according to the invention, which semiconductor chip can be seen in FIG. 5.

The method according to the invention can also be applied advantageously when one or more intermediate layers are situated between the semiconductor chip 1 and the layer sequence 2 in which the stepped profile is intended to be formed.

It is also possible, in an advantageous manner, to perform further patterning steps before, after or between the first, second and third patterning steps.

### LIST OF REFERENCE SYMBOLS

1 semiconductor chip
2 Layer sequence
21 Ag layer, first layer partial sequence
22 Ni layer, second layer partial sequence
23 Ti layer, third layer partial sequence
211 Ag residual layer
212 Ag final layer
221 Ni residual layer
3 protective layer, photoresist layer
A First projection
B Second projection

1. A method for forming a stepped profile from a layer sequence in which,
a) in a first patterning step, a first layer partial sequence is removed apart from a first residual layer partial sequence,
b) in a second patterning step, a second layer partial sequence located below the first layer partial sequence is partially removed by means of etching with a second etchant,
c) in a third patterning step, a third layer partial sequence located below the second layer partial sequence is partially removed by means of etching with a third etchant
wherein
d) in the second patterning step, a region of the second layer partial sequence that is located below the first residual layer partial sequence is removed, a first projection of the residual layer partial sequence being formed,
e) in the third patterning step, the first projection of the first residual layer partial sequence is removed.

2. The method as claimed in claim 1, wherein the second and third patterning steps are effected in aqueous solution.

3. The method as claimed in claim 1, wherein the first patterning step is carried out by means of etching with a first etchant.

4. The method as claimed in claim 3, wherein a substantially identical chemical composition is chosen for the first etchant and for the third etchant.

5. The method as claimed in claim 1, wherein, in the first patterning step, the first layer partial sequence is removed to an extent such that a second projection of the protective layer arises, which second projection has a length ti greater than a thickness d₁ of the first layer partial sequence.

6. The method as claimed in claim 1, wherein the first layer partial sequence substantially comprises Ag, the second layer partial sequence substantially comprises Ni, and the third layer partial sequence substantially comprises Ti.

7. The method as claimed in claim 1, wherein an aqueous solution of nitric acid, preferably in a dilution ratio of 1:z where 2.0<z<8.0, is used as the second etchant.

8. The method as claimed in claim 1, wherein a mixture of hydrogen peroxide, ammonium hydroxide and water, preferably in a volume ratio of approximately 1:x:y, is used as the first and third etchants, where 0.5<x<2.0 and 4.0<y 10.0.

9. The method as claimed in claim 1, wherein, prior to the first patterning step, a protective layer is provided on the first layer partial sequence.
